(19) United States
(12) Patent Application Publication
(10) Pub. No.: US 2014/0158394 A1
(43) Pub. Date: Jun. 12, 2014

(54) Electrical Junction Adapter for Luminaire Fixtures

(71) Applicant: Quarkstar LLC, Las Vegas, NV (US)

(72) Inventor: Edgar R. Velasquez, Daly City, CA (US)

(73) Assignee: Quarkstar LLC, Las Vegas, NV (US)

(21) Appl. No.: 14/061,526

(22) Filed: Oct. 23, 2013

Related U.S. Application Data
(60) Provisional application No. 61/734,849, filed on Dec. 7, 2012.

(51) Int. Cl. H05K 5/02

(52) U.S. Cl. CPC H05K 5/02
USPC 174/50

(57) ABSTRACT

In certain aspects, an adapter box includes a box having multiple walls and a bottom and a cover including a base plate and a second hinge portion, where a first hinge portion and the second hinge portion are configured to form a detachable hinge between the cover and the box in a hinged configuration. The adapter box further includes a locking mechanism configured to engage first and second locking portions and lock the cover to the box in the closed configuration. The cover is configured to attach to a luminaire and the box and cover are configured to allow electrical and mechanical interconnection of the luminaire to a source of power.

### CROSS-REFERENCE TO RELATED APPLICATION

This application claims the benefit under 35 U.S.C. §119(e)(1) of U.S. Provisional Application No. 61/734,849, filed on Dec. 7, 2012, which is incorporated by reference herein.

### BACKGROUND

Certain technologies can be used to fabricate an electrical junction adapter for light emitting diode (LED)-based luminaires.

### SUMMARY

In one aspect of the invention, an adapter box includes a box having multiple walls and a bottom. The walls are arranged to define an aperture opposite the bottom, and the box has a first hinge portion disposed on an edge of one of the multiple walls proximate the aperture. The box further includes a bolt protruding from a first wall and a first locking portion disposed on a second wall opposite the first hinge portion. The adapter box further includes a cover including a base plate and a second hinge portion, the first and second hinge portions configured to form a detachable hinge between the cover and the box in a hinged configuration. The cover further includes a side portion protruding substantially perpendicular from the base plate, the side portion having a curved aperture configured to slideably receive the bolt in the hinged configuration and allow hinging the cover relative to the box between an open and a closed configuration. The cover further includes a second locking portion opposite the second hinge portion. The adapter box further includes a locking mechanism configured to engage the first and second locking portions and lock the cover to the box in the closed configuration. The cover is configured to attach to a luminaire and the box and cover are configured to allow electrical and mechanical interconnection of the luminaire to a source of power.

In some embodiments, the bottom includes multiple apertures configured to align with multiple types of junction boxes.

One of skill in the art will appreciate that this disclosure is not limited to the embodiments described above and is intended to cover the embodiments described in this specification as well as other embodiments that are within the spirit and scope of the specification, the drawings, and the claims set forth below.

### DESCRIPTION OF DRAWINGS

FIGS. 1A-1B show different perspective views of an example adapter device.

FIG. 1C shows an exploded view of the example adapter device of FIGS. 1A-1B.

FIGS. 2A-2B show side views of an example attached luminaire including the adapter device of FIGS. 1A-1C and an example luminaire fixture.

Like reference numbers and designations in the various drawings indicate like elements.

### DETAILED DESCRIPTION

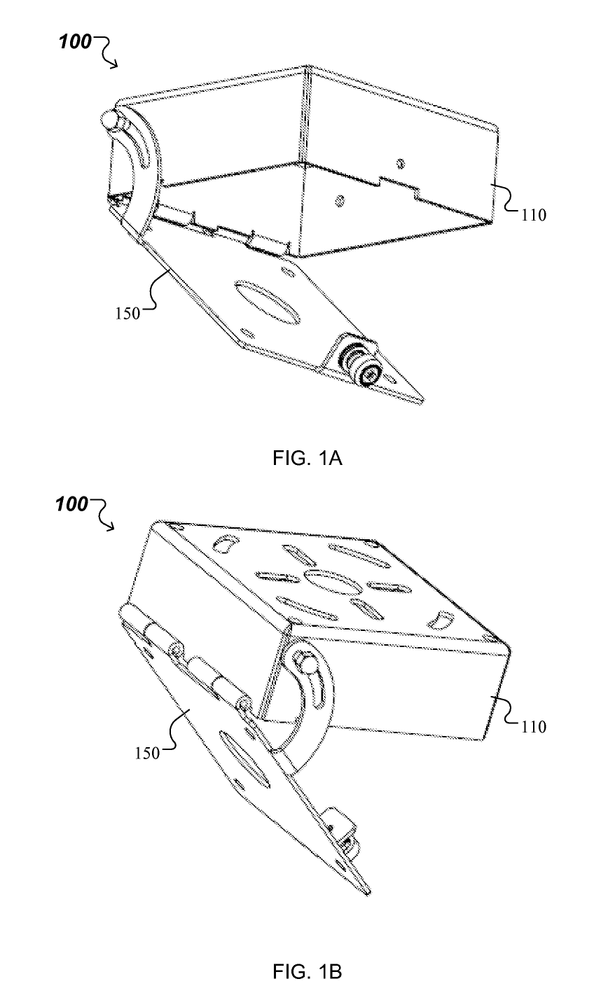

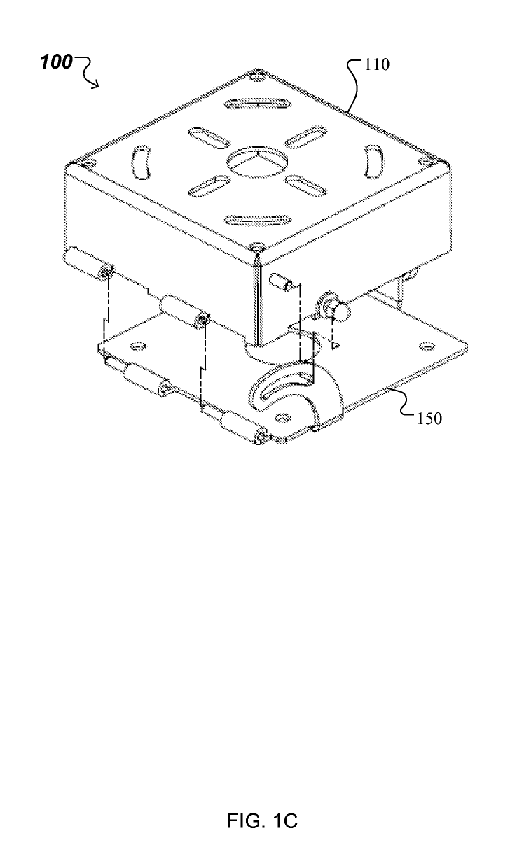

FIGS. 1A-1B show different perspective views of an example of an adapter device 100. FIG. 1C shows an exploded view of the adapter device 100. The adapter device 100 can be used as an electrical junction adapter for a luminaire fixture.

In some implementations, the adapter device 100 includes a box 110 that has multiple walls and a bottom. The walls are arranged to define an aperture opposite the bottom. The box 110 has a first hinge portion disposed on an edge of one of the multiple walls proximate the aperture. Further, the box 110 includes a bolt protruding from a first wall and a first locking portion disposed on a second wall opposite the first hinge portion. In some embodiments, the bottom includes multiple apertures configured to align with multiple types of electrical junction boxes.

A cover 150 includes a base plate and a second hinge portion. The first and second hinge portions are configured to form a detachable hinge between the cover 150 and the box 110 in a hinged configuration. The cover 150 further includes a side portion protruding substantially perpendicular from the base plate. The side portion has a curved aperture configured to slideably receive the bolt in the hinged configuration and to allow hinging the cover 150 relative to the box 110 between an open and a closed configuration. The cover 150 further includes a second locking portion opposite the second hinge portion.

The adapter device 100 also includes a locking mechanism configured to engage the first and second locking portions and lock the cover 150 to the box 110 in the closed configuration. Moreover, the cover 150 is configured to attach to a luminaire. Additionally, the box 110 and the cover 150 are configured to allow electrical and mechanical interconnection of the luminaire to a source of power.

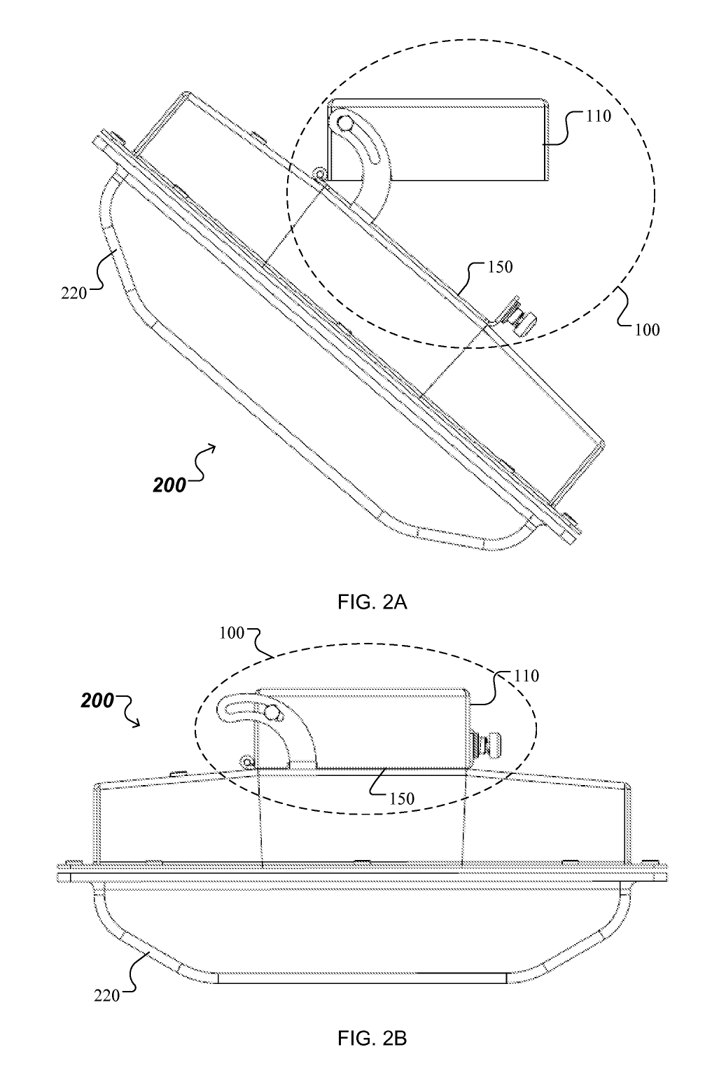

FIGS. 2A-2B show side views of an example of an attached luminaire 200 including the adapter device 100 and an example luminaire fixture 220. Light sources of the luminaire fixture 220 can be light emitting diodes (LEDs). As described above in connection with FIGS. 1A-1C, the adapter device includes a box 110 and a cover 150. The bottom of the box 110 can be attached to an electrical junction box when the attached luminaire 200 is being operated. For example, the electrical junction box can protrude below the ceiling, or can be flush with the ceiling. In some configurations, the cover 150 is attached to the luminaire fixture 220. In other implementations, the cover 150 is part of the luminaire fixture 220.

FIG. 2A shows an open configuration of the adapter 100. In the open configuration, electrical connections of the luminaire fixture 220 can be connected or disconnected from a source of power, for instance. FIG. 2B shows a closed configuration of the adapter 100. This configuration represents an operational configuration for the attached luminaire 220, for instance.

A number of embodiments have been described. Nevertheless, it will be understood that various modifications may be made without departing from the spirit and scope of the claims. For example, an adapter device may include features that have dimensions, shapes, numbers, positions, and/or arrangements different from those of the adapter device described.

What is claimed is:

1. An adapter device comprising:
a box having a plurality of walls and a bottom, the walls arranged to define an aperture opposite the bottom, the box having a first hinge portion disposed on an edge of one of the plurality of walls proximate the aperture, the box further comprising a bolt protruding from a first wall and a first locking portion disposed on a second wall opposite the first hinge portion;
a cover comprising a base plate and a second hinge portion, the first and second hinge portions configured to form a detachable hinge between the cover and the box in a hinged configuration; the cover further comprising a side portion protruding substantially perpendicular from the base plate, the side portion having a curved aperture configured to slideably receive the bolt in the hinged configuration and allow hinging the cover relative to the box between an open and a closed configuration; the cover further comprising a second locking portion opposite the second hinge portion; and
a locking mechanism configured to engage the first and second locking portions and lock the cover to the box in the closed configuration,
wherein the cover is configured to attach to a luminaire and the box and cover are configured to allow electrical and mechanical interconnection of the luminaire to a source of power.

2. The adapter device of claim 1, wherein the bottom includes multiple apertures configured to align with multiple types of junction boxes.
